(19) United States
(12) Patent Application Publication
(10) Pub. No.: US 2026/0045917 A1
(43) Pub. Date: Feb. 12, 2026

(54) AMPLIFIER CIRCUIT

(71) Applicant: Murata Manufacturing Co., Ltd., Nagaokakyo-shi (JP)

(72) Inventor: Naoki MORIKAWA, Nagaokakyo-shi (JP)

(21) Appl. No.: 19/264,960

(22) Filed: Jul. 10, 2025

(30) Foreign Application Priority Data
Aug. 6, 2024 (JP) 2024-129989

(51) Int. Cl. H03F 1/22; H03F 3/195; H03F 3/72

(52) U.S. Cl. CPC H03F 1/223; H03F 3/195; H03F 3/72; H03F 2200/451; H03F 2203/7206

(57) ABSTRACT

An amplifier circuit includes an input terminal; an output terminal; an FET 11 including a gate terminal g1, a drain terminal d1, and a source terminal s1; an FET 12 including a gate terminal g2, a drain terminal d2, and a source terminal s2; an FET 31 including a gate terminal g3, a drain terminal d3, and a source terminal s3; and LC parallel resonant circuits. The gate terminal g1 is connected to the input terminal, the drain terminal d1 is connected to the source terminal s2, the source terminal s1 is connected to the ground, the gate terminal g2 is connected to the drain terminal d3 and the LC parallel resonant circuit, the drain terminal d2 is connected to the output terminal and the LC parallel resonant circuit, the gate terminal g3 is connected to the source terminal s2, and the source terminal s3 is connected to the ground.

### CROSS REFERENCE TO RELATED APPLICATION

This application claims priority from Japanese Patent Application No. 2024-129989, filed on Aug. 6, 2024. The content of this application is incorporated herein by reference in its entirety.

### BACKGROUND OF THE DISCLOSURE

### 1. Field of the Disclosure

The present disclosure relates to an amplifier circuit.

### 2. Description of the Related Art

Japanese Unexamined Patent Application Publication (Translation of PCT Application) No. 2008-512926 discloses a low noise amplifier circuit including two cascoded amplifying elements.

### BRIEF SUMMARY OF THE DISCLOSURE

In the amplifier circuit disclosed in Japanese Unexamined Patent Application Publication (Translation of PCT Application) No. 2008-512926, methods for further increasing the gain include: increasing the transconductance by increasing the current consumption (drain current or collector), and increasing the output resistance by employing a multistage configuration including three or more amplifying elements. However, with the above methods, because the current consumption or the power supply voltage increases, it is not possible to achieve high gain while maintaining low power consumption.

The present disclosure has been made to solve the above problem, and a possible benefit of the present disclosure is to provide an amplifier circuit with increased gain while maintaining power consumption.

To achieve the above possible benefit, an amplifier circuit according to an aspect of the present disclosure includes a first input terminal; a first output terminal; a first amplifying element including a first control terminal, a first terminal, and a second terminal; a second amplifying element including a second control terminal, a third terminal, and a fourth terminal; a third amplifying element including a third control terminal, a fifth terminal, and a sixth terminal; a first LC parallel resonant circuit; and a second LC parallel resonant circuit. The first control terminal is connected to the first input terminal, the first terminal is connected to the fourth terminal, the second terminal is connected to the ground, the second control terminal is connected to the fifth terminal and the second LC parallel resonant circuit, the third terminal is connected to the first output terminal and the first LC parallel resonant circuit, the third control terminal is connected to the fourth terminal, and the sixth terminal is connected to the ground.

The present disclosure makes it possible to provide an amplifier circuit with increased gain while maintaining low power consumption.

### BRIEF DESCRIPTION OF THE SEVERAL VIEWS OF THE DRAWINGS

FIG. 1 is a circuit diagram of an amplifier circuit according to an embodiment;

FIG. 2A is a circuit diagram of an amplifier circuit according to a comparative example;

FIG. 2B is a diagram showing the current-voltage characteristics of amplifying elements according to the embodiment and the comparative example;

FIG. 3 is a circuit diagram of an amplifier circuit according to a first variation of the embodiment;

FIG. 4A is a circuit state diagram of the amplifier circuit in a high-gain mode according to the first variation of the embodiment;

FIG. 4B is a circuit state diagram of the amplifier circuit in a low-gain mode according to the first variation of the embodiment;

FIG. 5 is a circuit diagram of an amplifier circuit according to a second variation of the embodiment;

FIG. 6 is a circuit diagram of an amplifier circuit according to a third variation of the embodiment;

FIG. 7 is a circuit diagram of an amplifier circuit according to a fourth variation of the embodiment;

FIG. 8A is a circuit state diagram of the amplifier circuit according to the fourth variation of the embodiment in which a first amplifier is in operation; and

FIG. 8B is a circuit state diagram of the amplifier circuit according to the fourth variation of the embodiment in which a second amplifier is in operation.

### DETAILED DESCRIPTION OF THE DISCLOSURE

Embodiments of the present disclosure are described in detail below with reference to the drawings. Each of the embodiments described below represents a general or specific example. Values, shapes, materials, components, and layouts and connection configurations of the components described in the embodiments below are just examples and are not intended to limit the present disclosure.

Each of the drawings is a schematic diagram in which components are emphasized or omitted and the ratios between the components are adjusted to facilitate the understanding of the present disclosure. That is, components in each of the drawings are not necessarily illustrated accurately; and the shapes, positional relationships, and ratios of the components may differ from the actual shapes, positional relationships, and ratios. The same reference number is assigned to substantially the same components in the drawings, and repeated descriptions of those components may be omitted or simplified.

In circuit configurations of the present disclosure, “connected” not only indicates that circuit elements are directly connected to each other with a connection terminal and/or a wire conductor but also indicates that the circuit elements are electrically connected to each other via another circuit element. Also, “connected between A and B” indicates that a component is disposed between A and B and is connected to both of A and B.

Also, in the present disclosure, “path” indicates a transmission line that is constituted by, for example, a wire for transmitting a radio frequency signal, an electrode directly connected to the wire, and a terminal directly connected to the wire or the electrode.

In the present disclosure, “component A is disposed in series with path B” means that each of a signal input end and a signal output end of the component A is connected to one of a wire, an electrode, and a terminal constituting the path B.

In the present disclosure, each of “terminal”, “input end”, and “output end” indicates a point at which a conductor in an element ends. Here, when the impedance of a conductor between elements is sufficiently low, a terminal is interpreted not only as a single point but also as any point on the conductor between the elements or the entire conductor.

### Embodiment

### 1 Circuit Configuration of Amplifier Circuit 1

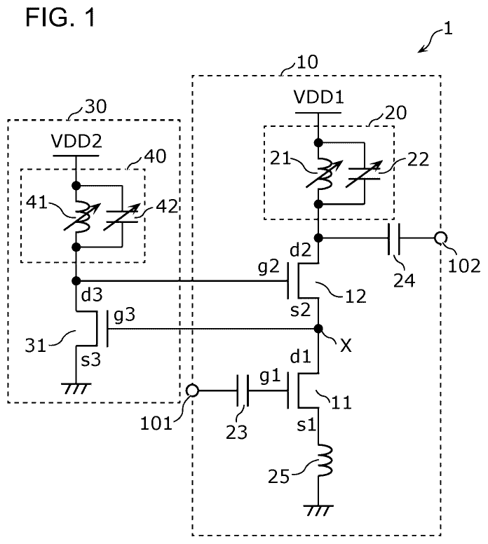

A circuit configuration of an amplifier circuit 1 according to an embodiment is described with reference to FIG. 1. FIG. 1 is a circuit diagram of the amplifier circuit 1 according to the embodiment. As illustrated in FIG. 1, the amplifier circuit 1 includes an amplifier 10 and an auxiliary amplifier 30. The amplifier 10 includes an input terminal 101, an output terminal 102, FETs 11 and 12, an LC parallel resonant circuit 20, capacitors 23 and 24, and an inductor 25. The auxiliary amplifier 30 includes an FET 31 and an LC parallel resonant circuit 40.

The input terminal 101 is an example of a first input terminal to which a radio frequency signal is inputted. The output terminal 102 is an example of a first output terminal that outputs a radio frequency signal.

The FET 11 is an example of a first amplifying element, which is an n-channel metal-oxide-semiconductor field-effect transistor (MOSFET), and includes a gate terminal g1 (first control terminal), a drain terminal d1 (first terminal), and a source terminal s1 (second terminal). The FET 12 is an example of a second amplifying element, which is an n-channel MOSFET, and includes a gate terminal g2 (second control terminal), a drain terminal d2 (third terminal), and a source terminal s2 (fourth terminal). The FET 31 is an example of a third amplifying element, which is an n-channel MOSFET, and includes a gate terminal g3 (third control terminal), a drain terminal d3 (fifth terminal), and a source terminal s3 (sixth terminal).

Each of the FETs 11, 12, and 31 may instead be a p-channel MOSFET or any other type of FET. When each of the FETs 11, 12, and 31 is a p-channel MOSFET, the positions of the drain terminal and the source terminal are exchanged. Moreover, each of the FETs 11, 12, and 31 may be a bipolar transistor. When each of the FETs 11, 12, and 31 is a bipolar transistor, the gate terminal of the FET is replaced with a base terminal, the drain terminal of the FET is replaced with a collector terminal, and the source terminal of the FET is replaced with an emitter terminal.

The LC parallel resonant circuit 20 is an example of a first LC parallel resonant circuit and has a configuration in which a variable inductor 21 is connected in parallel with a variable capacitor 22. The LC parallel resonant circuit 20 varies the resonant frequency according to the frequency of a radio frequency signal inputted to the input terminal 101. The LC parallel resonant circuit 40 is an example of a second LC parallel resonant circuit and has a configuration in which a variable inductor 41 is connected in parallel with a variable capacitor 42. The LC parallel resonant circuit 40 varies the resonant frequency according to the frequency of a radio frequency signal inputted to the input terminal 101. Here, each of the LC parallel resonant circuits 20 and 40 does not necessarily include the function for varying the resonant frequency.

The gate terminal g1 is connected to the input terminal 101 via the capacitor 23. The drain terminal d1 is connected to the source terminal s2. The source terminal s1 is connected to a ground via the inductor 25. The gate terminal g2 is connected to the drain terminal d3 and the LC parallel resonant circuit 40. The drain terminal d2 is connected to the output terminal 102 via the capacitor 24 and is also connected to the LC parallel resonant circuit 20. The gate terminal g3 is connected to the source terminal s2. The source terminal s3 is connected to the ground.

With the above connection configuration, the FETs 11 and 12 are cascoded, and therefore the amplifier circuit 1 can function as a high-gain amplifier circuit.

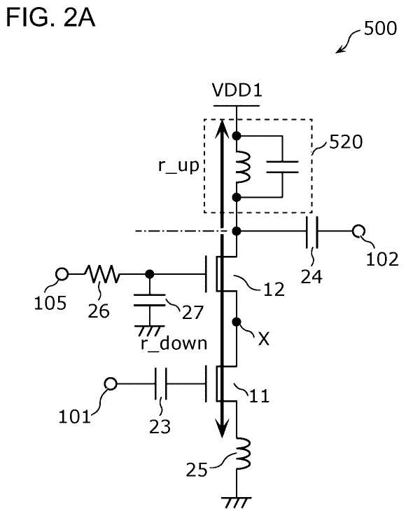

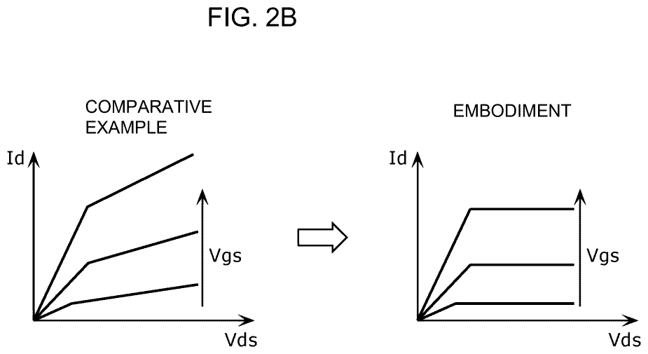

Here, for comparison, an example of a related-art cascode amplifier circuit is described. FIG. 2A is a circuit diagram of an amplifier circuit 500 according to a comparative example. As illustrated in FIG. 2A, the amplifier circuit 500 according to the comparative example is a related-art cascode amplifier circuit and includes an input terminal 101, an output terminal 102, a bias terminal 105, FETs 11 and 12, an LC parallel resonant circuit 520, capacitors 23, 24, and 27, an inductor 25, and a resistor element 26. The amplifier circuit 500 according to the comparative example differs from the amplifier circuit 1 according to the embodiment in that the amplifier circuit 500 does not include the auxiliary amplifier 30.

The FETs 11 and 12 are cascoded. Generally, in a low noise amplifier circuit, a cascode structure is used to achieve high gain. In the amplifier circuit 500, gain A is defined by Formula 1.

$$A = gm 1 \times Rout \qquad ( Formula 1 )$$

In Formula 1, gm1 represents the mutual conductance of the FET 11, and Rout represents output resistance that is expressed by Formula 2.

$$Rout = r\_up // r\_down = r\_up \times r\_down / ( r\_up + r\_down ) \qquad ( Formula 2 )$$

In Formula 2, r_up represents impedance that is observed when the power supply side is viewed from the drain terminal of the FET 12, and r_down represents impedance that is observed when the ground side is viewed from the drain terminal of the FET 12. That is, the output resistance Rout is the parallel impedance of r_up and r_down.

According to Formula 1, for example, the gain A can be increased by (1) increasing gm1 by increasing the current consumption (the drain current Id); or (2) increasing the output resistance Rout FET by employing a multistage configuration including three or more FETs.

However, the method (1) results in increased current consumption. Also, once gm1 saturates, the gain does not increase even when the current is further increased. Also, when a multistage configuration is employed according to the method (2), no low supply voltage circuit can be used. That is, with the methods (1) and (2) described above, it is difficult to increase gain while achieving low power consumption.

In contrast, with the amplifier circuit 1 according to the present embodiment, it is possible to increase the output resistance Rout without increasing power consumption. Regarding r_up, the resonant frequency of the LC parallel resonant circuit 20 is adjusted so that high impedance is obtained at the frequency of the radio frequency signal. On the other hand, regarding r_down, high impedance can be achieved by providing the auxiliary amplifier 30 and thereby reducing the potential amplitude at a point X (the connection point between the drain terminal d1 of the FET 11 and the source terminal s2 of the FET 12).

In the amplifier circuit 500 according to the comparative example, a potential Vg2 at the gate terminal of the FET 12 is fixed by a bias potential supplied from the bias terminal 105. Therefore, when the drain current Id, the amplitude of which varies at a high frequency, is caused to flow, a gate-source voltage Vgs2 of the FET 12 varies. Because the gate-source voltage Vgs2 corresponds to (Vg2−Vx), where Vx represents the potential at the X point, Vx also varies according to the amplitude variation of the drain current Id.

In contrast, in the amplifier circuit 1 according to the present embodiment, because the gate terminal g2 of the FET 12 is connected to the drain terminal d3 of the auxiliary amplifier 30, the potential Vg2 at the gate terminal g2 varies according to the amplitude variation in the drain current Id. Therefore, because the gate-source voltage Vgs2 corresponds to (Vg2−Vx), Vx does not vary according to the amplitude variation in the drain current Id.

FIG. 2B is a diagram showing the current-voltage characteristics of the FETs 12 according to the embodiment and the comparative example. In the amplifier circuit 500 according to the comparative example, because Vx varies greatly, the amplitude of the drain current Id also increases and decreases according to the variation in a drain-source voltage Vds of the FET 12. In contrast, in the amplifier circuit 1 according to the embodiment, because the variation of Vx is small, the drain-source voltage Vds of the FET 12 does not vary, and the amplitude of the drain current Id varies depending on the gate-source voltage Vgs. In this case, the drain current Id does not vary depending on the variation in the drain-source voltage Vds. This is equivalent to the drain-source resistance of the FET 12 being very high. This in turn makes it possible to increase r_down. That is, in the amplifier circuit 1 according to the embodiment, it is possible to greatly increase the output resistance Rout and thereby increase the gain A by applying a small electric current to the auxiliary amplifier 30. This in turn makes it possible to provide the amplifier circuit 1 with increased gain while maintaining low power consumption.

### 2 Circuit Configuration of Amplifier Circuit 2 According to First Variation

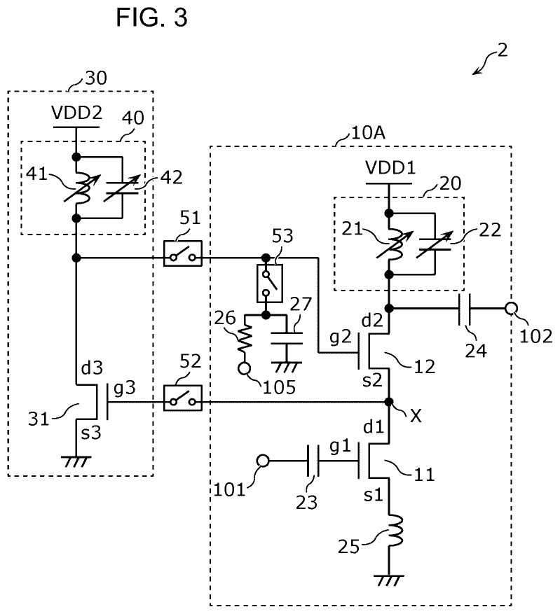

FIG. 3 is a circuit diagram of an amplifier circuit 2 according to a first variation of the embodiment. As illustrated in FIG. 3, the amplifier circuit 2 according to the present variation includes an amplifier 10A, an auxiliary amplifier 30, and switches 51 and 52. The amplifier circuit 2 according to the present variation differs from the amplifier circuit 1 according to the embodiment in the configuration of the amplifier 10A and the addition of the switches 51 and 52. Below, descriptions of configurations of the amplifier circuit 2 of the present variation identical to those of the amplifier circuit 1 of the embodiment are omitted, and different configurations are mainly described.

The amplifier 10A includes an input terminal 101, an output terminal 102, FETs 11 and 12, an LC parallel resonant circuit 20, capacitors 23, 24, and 27, an inductor 25, a resistor element 26, and a switch 53.

The switch 53 is connected between the gate terminal g2 and a combination of the capacitor 27 and the resistor element 26. The capacitor 27 is connected between the switch 53 and the ground and serves as a gate-ground capacitance of the FET 12. The resistor element 26 is connected between the switch 53 and the bias terminal 105.

The switch 52 is an example of a first switch, is connected between the source terminal s2 and the gate terminal g3, and connects and disconnects the source terminal s2 and the gate terminal g3. The switch 51 is an example of a second switch, is connected between the gate terminal g2 and the drain terminal d3, and connects and disconnects the gate terminal g2 and the drain terminal d3.

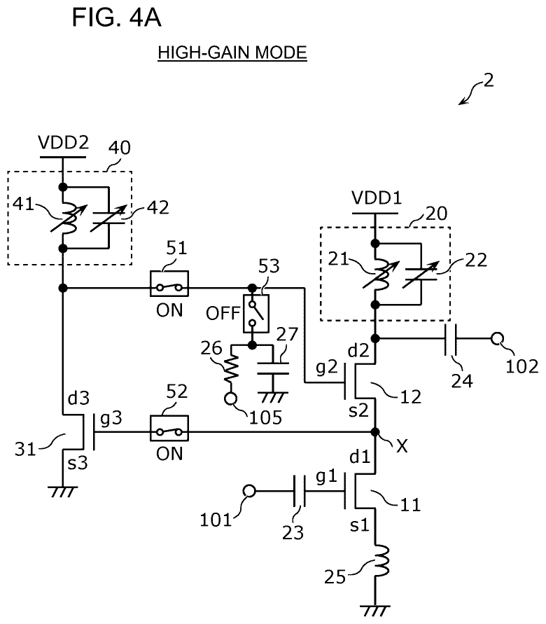

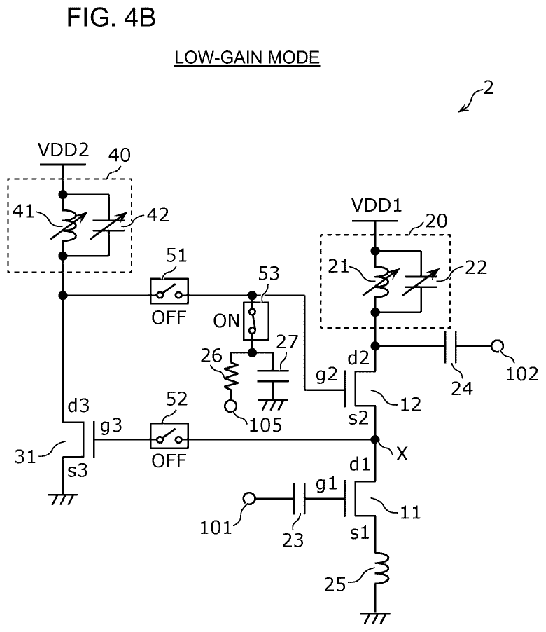

FIG. 4A is a circuit state diagram of the amplifier circuit 2 in a high-gain mode according to the first variation of the embodiment. When the amplifier circuit 2 requires gain greater than a predetermined value, the switches 51 and 52 transition to a conductive state. On the other hand, the switch 53 transitions to a non-conductive state. As a result, the auxiliary amplifier 30 is connected to the amplifier 10A, and the amplifier circuit 2 is enabled to amplify a radio frequency signal inputted to the input terminal 101 with high gain while maintaining low power consumption.

FIG. 4B is a circuit state diagram of the amplifier circuit 2 in a low-gain mode according to the first variation of the embodiment. When the amplifier circuit 2 requires gain less than or equal to the predetermined value, the switches 51 and 52 transition to a non-conductive state. On the other hand, the switch 53 transitions to a conductive state. As a result, the auxiliary amplifier 30 is not connected to the amplifier 10A, the gate terminal g2 is high-frequency grounded, a bias voltage is supplied from the bias terminal 105 to the gate terminal g2, and the amplifier circuit 2 is enabled to amplify a radio frequency signal inputted to the input terminal 101 with low gain.

With this configuration, the amplifier circuit 2 can select either the low-gain mode or the high-gain mode with low power consumption as appropriate by controlling the switches 51 to 53.

### 3 Circuit Configuration of Amplifier Circuit 3 According to Second Variation

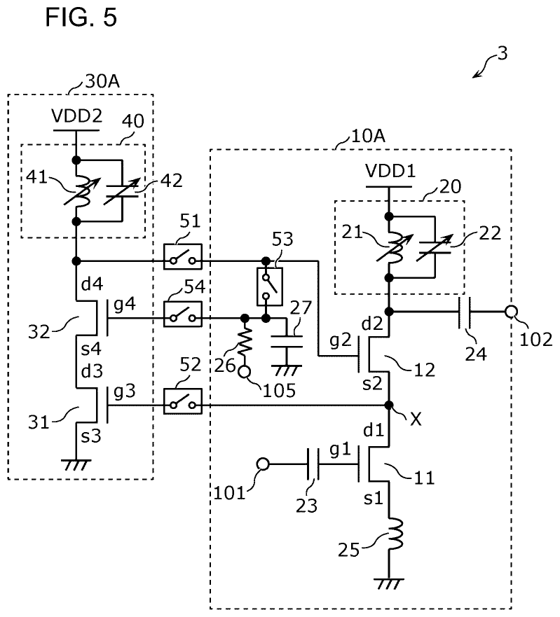

FIG. 5 is a circuit diagram of an amplifier circuit 3 according to a second variation of the embodiment. As illustrated in FIG. 5, the amplifier circuit 3 according to the present variation includes an amplifier 10A, an auxiliary amplifier 30A, and switches 51, 52, and 54. The amplifier circuit 3 according to the present variation differs from the amplifier circuit 2 according to the first variation in the configuration of the auxiliary amplifier 30A and the addition of a switch 54. Below, descriptions of configurations of the amplifier circuit 3 of the present variation identical to those of the amplifier circuit 2 of the first variation are omitted, and different configurations are mainly described.

The auxiliary amplifier 30A includes FETs 31 and 32 and an LC parallel resonant circuit 40.

The FET 32 is an example of a fourth amplifying element, is an n-channel MOSFET, and includes a gate terminal g4 (fourth control terminal), a drain terminal d4 (seventh terminal), and a source terminal s4 (eighth terminal).

The FET 32 may instead be a p-channel MOSFET or any other type of FET. When the FET 32 is a p-channel MOSFET, the positions of the drain terminal and the source terminal are exchanged. The FET 32 may also be a bipolar transistor. When the FET 32 is a bipolar transistor, the gate terminal of the FET 32 is replaced with a base terminal, the drain terminal of the FET 32 is replaced with a collector terminal, and the source terminal of the FET 32 is replaced with an emitter terminal.

The FET 32 is connected between the drain terminal d3 and the LC parallel resonant circuit 40. The gate terminal g4 is connected to the bias terminal 105 via the switch 54. The drain terminal d4 is connected to the LC parallel resonant circuit 40. The source terminal s4 is connected to the drain terminal d3. The gate terminal g2 is connected to the drain terminal d3 via the drain terminal d4 and the source terminal s4. The gate terminal g3 is connected to the source terminal s2 via the switch 52. The source terminal s3 is connected to the ground.

With the above connection configuration, the FET 31 and the FET 32 are cascoded. This makes it possible to provide the amplifier circuit 3 that achieves high gain with lower current consumption. Also, the above configuration makes it possible to suppress the miller effect in the auxiliary amplifier 30A and thereby makes it possible to improve reverse isolation and improve the K factor.

### 4 Circuit Configuration of Amplifier Circuit 4 According to Third Variation

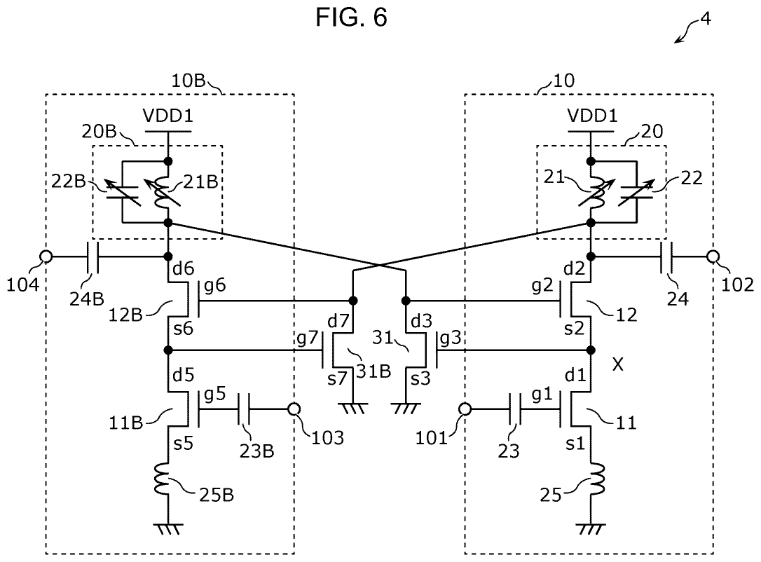

FIG. 6 is a circuit diagram of an amplifier circuit 4 according to a third variation of the embodiment. As illustrated in FIG. 6, the amplifier circuit 4 according to the present variation includes amplifiers 10 and 10B and FETs 31 and 31B. The amplifier circuit 4 according to the present variation differs from the amplifier circuit 1 according to the embodiment in that the amplifier circuit 4 includes two amplifiers 10 and 10B, uses a part of the amplifier 10B as an auxiliary amplifier for the amplifier 10, and uses a part of the amplifier 10 as an auxiliary amplifier for the amplifier 10B. Below, descriptions of configurations of the amplifier circuit 4 of the present variation identical to those of the amplifier circuit 1 of the embodiment are omitted, and different configurations are mainly described.

The amplifier 10 includes an input terminal 101, an output terminal 102, FETs 11 and 12, an LC parallel resonant circuit 20, capacitors 23 and 24, and an inductor 25. The amplifier 10 has the same configuration as the amplifier 10 of the amplifier circuit 1 according to the embodiment.

The amplifier 10B includes an input terminal 103, an output terminal 104, FETs 11B and 12B, an LC parallel resonant circuit 20B, capacitors 23B and 24B, and an inductor 25B.

The input terminal 103 is an example of a second input terminal to which a radio frequency signal is inputted. The output terminal 104 is an example of a second output terminal that outputs a radio frequency signal.

The FET 11B is an example of a fifth amplifying element, is an n-channel MOSFET, and includes a gate terminal g5 (fifth control terminal), a drain terminal d5 (ninth terminal), and a source terminal s5 (tenth terminal). The FET 12B is an example of a sixth amplifying element, is an n-channel MOSFET, and includes a gate terminal g6 (sixth control terminal), a drain terminal d6 (eleventh terminal), and a source terminal s6 (twelfth terminal).

Each of the FETs 11B and 12B may instead be a p-channel MOSFET or any other type of FET. When each of the FETs 11B and 12B is a p-channel MOSFET, the positions of the drain terminal and the source terminal are exchanged. Also, each of the FETs 11B and 12B may be a bipolar transistor. When each of the FETs 11B and 12B is a bipolar transistor, the gate terminal of the FET is replaced with a base terminal, the drain terminal of the FET is replaced with a collector terminal, and the source terminal of the FET is replaced with an emitter terminal.

The LC parallel resonant circuit 20B is an example of a second LC parallel resonant circuit and has a configuration in which a variable inductor 21B is connected in parallel with a variable capacitor 22B. The LC parallel resonant circuit 20B varies the resonant frequency according to the frequency of a radio frequency signal inputted to the input terminal 103. Here, the LC parallel resonant circuit 20B does not necessarily include the function for varying the resonant frequency.

The gate terminal g1 is connected to the input terminal 101 via the capacitor 23. The drain terminal d1 is connected to the source terminal s2. The source terminal s1 is connected to the ground via the inductor 25. The gate terminal g2 is connected to the drain terminal d6 and the LC parallel resonant circuit 20B. The drain terminal d2 is connected to the output terminal 102 via the capacitor 24 and is also connected to the LC parallel resonant circuit 20.

The gate terminal g5 is connected to the input terminal 103 via the capacitor 23B. The drain terminal d5 is connected to the source terminal s6. The source terminal s5 is connected to the ground via the inductor 25B. The gate terminal g6 is connected to the drain terminal d2 and the LC parallel resonant circuit 20. The drain terminal d6 is connected to the output terminal 104 via the capacitor 24B and is also connected to the LC parallel resonant circuit 20B.

The FET 31 is an example of a third amplifying element, is an n-channel MOSFET, and includes a gate terminal g3 (third control terminal), a drain terminal d3 (fifth terminal), and a source terminal s3 (sixth terminal). The FET 31B is an example of a seventh amplifying element, is an n-channel MOSFET, and includes a gate terminal g7 (seventh control terminal), a drain terminal d7 (thirteenth terminal), and a source terminal s7 (fourteenth terminal).

The gate terminal g3 is connected to the source terminal s2. The drain terminal d3 is connected to the gate terminal g2 and the LC parallel resonant circuit 20B. The source terminal s3 is connected to the ground. The gate terminal g7 is connected to the source terminal s6. The drain terminal d7 is connected to the gate terminal g6 and the LC parallel resonant circuit 20. The source terminal s7 is connected to the ground.

With the above connection configuration, the FET 11 and the FET 12 are cascoded, and the FET 11B and the FET 12B are cascoded.

In the above circuit configuration, for example, when a radio frequency signal is inputted from the input terminal 101, amplified by the amplifier 10, and then outputted from the output terminal 102, the FETs 11B, 12B, and 31B are turned off, and the FET 31 and the LC parallel resonant circuit 20B function as an auxiliary amplifier for the amplifier 10. Also, for example, when a radio frequency signal is inputted from the input terminal 103, amplified by the amplifier 10B, and then outputted from the output terminal 104, the FETs 11, 12, and 31 are turned off, and the FET 31B and the LC parallel resonant circuit 20 function as an auxiliary amplifier for the amplifier 10B.

The above configuration makes it possible to use a part (an LC parallel resonant circuit) of an amplifier in the off state as an auxiliary amplifier. This in turn makes it possible to provide the amplifier circuit 4 with increased gain and less area while maintaining low power consumption.

### 5 Circuit Configuration of Amplifier Circuit 5 According to Fourth Variation

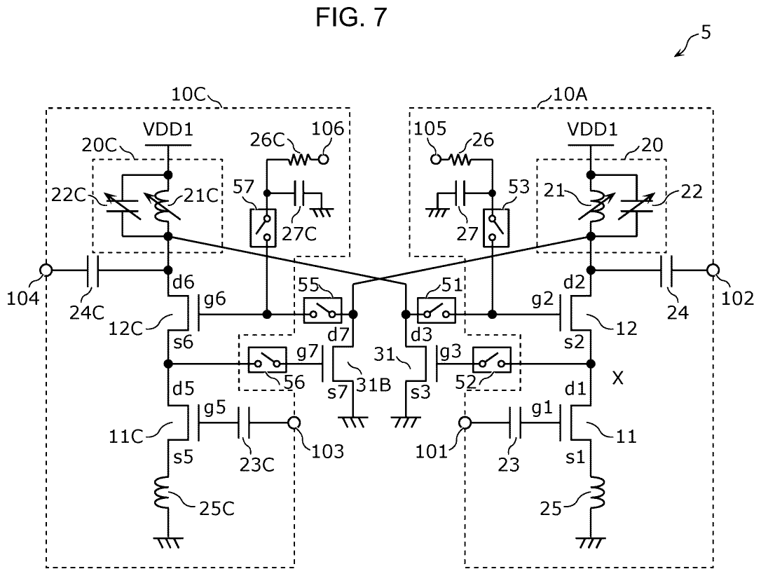

FIG. 7 is a circuit diagram of an amplifier circuit 5 according to a fourth variation of the embodiment. As illustrated in FIG. 7, the amplifier circuit 5 according to the present variation includes amplifiers 10A and 10C, FETs 31 and 31B, and switches 51, 52, 55, and 56. The amplifier circuit 5 according to the present variation differs from the amplifier circuit 3 according to the second variation in that the amplifier circuit 5 includes two amplifiers 10A and 10C, uses a part of the amplifier 10C as an auxiliary amplifier for the amplifier 10A, and uses a part of the amplifier 10A as an auxiliary amplifier for the amplifier 10C. Below, descriptions of configurations of the amplifier circuit 5 of the present variation identical to those of the amplifier circuit 3 of the second variation are omitted, and different configurations are mainly described.

The amplifier 10A includes an input terminal 101, an output terminal 102, FETs 11 and 12, an LC parallel resonant circuit 20, capacitors 23, 24, and 27, an inductor 25, a resistor element 26, and a switch 53. The amplifier 10A has the same configuration as the amplifier 10A of the amplifier circuit 2 according to the first variation and the amplifier 10A of the amplifier circuit 3 according to the second variation.

The amplifier 10C includes an input terminal 103, an output terminal 104, FETs 11C and 12C, an LC parallel resonant circuit 20C, capacitors 23C, 24C, and 27C, an inductor 25C, a resistor element 26C, and a switch 57.

The input terminal 103 is an example of a second input terminal to which a radio frequency signal is inputted. The output terminal 104 is an example of a second output terminal that outputs a radio frequency signal.

The FET 11C is an example of a fifth amplifying element, is an n-channel MOSFET, and includes a gate terminal g5 (fifth control terminal), a drain terminal d5 (ninth terminal), and a source terminal s5 (tenth terminal). The FET 12C is an example of a sixth amplifying element, is an n-channel MOSFET, and includes a gate terminal g6 (sixth control terminal), a drain terminal d6 (eleventh terminal), and a source terminal s6 (twelfth terminal).

Each of the FETs 11C and 12C may instead be a p-channel MOSFET or any other type of FET. When each of the FETs 11C and 12C is a p-channel MOSFET, the positions of the drain terminal and the source terminal are exchanged. Also, each of the FETs 11C and 12C may be a bipolar transistor. When each of the FETs 11C and 12C is a bipolar transistor, the gate terminal of the FET is replaced with a base terminal, the drain terminal of the FET is replaced with a collector terminal, and the source terminal of the FET is replaced with an emitter terminal.

The LC parallel resonant circuit 20C is an example of a second LC parallel resonant circuit and has a configuration in which a variable inductor 21C is connected in parallel with a variable capacitor 22C. The LC parallel resonant circuit 20C varies the resonant frequency according to the frequency of a radio frequency signal inputted to the input terminal 103. Here, the LC parallel resonant circuit 20C does not necessarily include the function for varying the resonant frequency.

The switch 53 is connected between the gate terminal g2 and a combination of the capacitor 27 and the resistor element 26. The capacitor 27 is connected between the switch 53 and the ground and serves as a gate-ground capacitance of the FET 12. The resistor element 26 is connected between the switch 53 and the bias terminal 105.

The switch 57 is connected between the gate terminal g6 and a combination of the capacitor 27C and the resistor element 26C. The capacitor 27C is connected between the switch 57 and the ground and serves as a gate-ground capacitance of the FET 12C. The resistor element 26C is connected between the switch 57 and a bias terminal 106.

The switch 52 is an example of a third switch, is connected between the source terminal s2 and the gate terminal g3, and connects and disconnects the source terminal s2 and the gate terminal g3. The switch 51 is an example of a fourth switch, is connected between the gate terminal g2 and the drain terminal d3, and connects and disconnects the gate terminal g2 and the drain terminal d3. The switch 56 is an example of a fifth switch, is connected between the source terminal s6 and the gate terminal g7, and connects and disconnects the source terminal s6 and the gate terminal g7. The switch 55 is an example of a sixth switch, is connected between the gate terminal g6 and the drain terminal d2, and connects and disconnects the gate terminal g6 and the drain terminal d2.

The gate terminal g1 is connected to the input terminal 101 via the capacitor 23. The drain terminal d1 is connected to the source terminal s2. The source terminal s1 is connected to the ground via the inductor 25. The gate terminal g2 is connected via the switch 51 to the drain terminal d6 and the LC parallel resonant circuit 20C. The drain terminal d2 is connected to the output terminal 102 via the capacitor 24 and is also connected to the LC parallel resonant circuit 20.

The gate terminal g5 is connected to the input terminal 103 via the capacitor 23C. The drain terminal d5 is connected to the source terminal s6. The source terminal s5 is connected to the ground via the inductor 25C. The gate terminal g6 is connected via the switch 55 to the drain terminal d2 and the LC parallel resonant circuit 20. The drain terminal d6 is connected to the output terminal 104 via the capacitor 24C and is also connected to the LC parallel resonant circuit 20C.

The FET 31 is an example of a third amplifying element, is an n-channel MOSFET, and includes a gate terminal g3 (third control terminal), a drain terminal d3 (fifth terminal), and a source terminal s3 (sixth terminal). The FET 31B is an example of a seventh amplifying element, is an n-channel MOSFET, and includes a gate terminal g7 (seventh control terminal), a drain terminal d7 (thirteenth terminal), and a source terminal s7 (fourteenth terminal).

The gate terminal g3 is connected to the source terminal s2 via the switch 52. The drain terminal d3 is connected to the gate terminal g2 via the switch 51 and is also connected to the LC parallel resonant circuit 20C. The source terminal s3 is connected to the ground. The gate terminal g7 is connected to the source terminal s6 via the switch 56. The drain terminal d7 is connected to the gate terminal g6 via the switch 55 and is also connected to the LC parallel resonant circuit 20. The source terminal s7 is connected to the ground.

With the above connection configuration, the FET 11 and the FET 12 are cascoded, and the FET 11C and the FET 12C are cascoded.

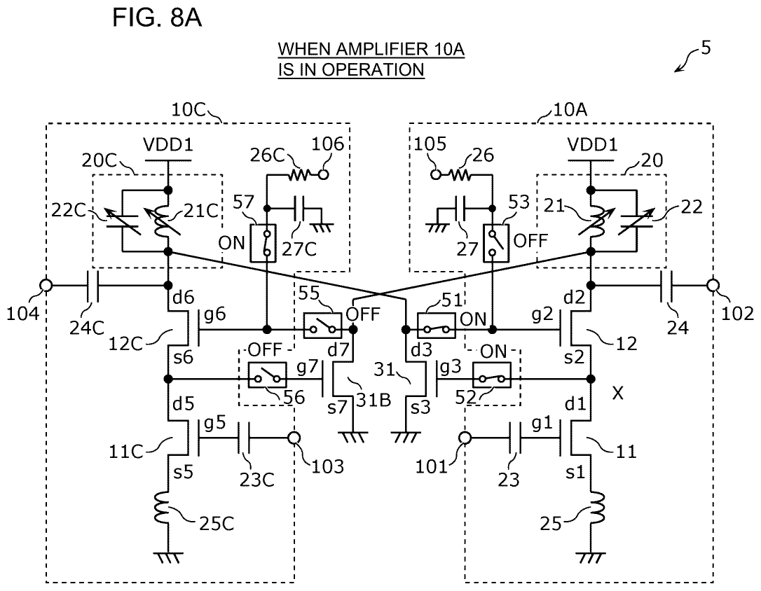

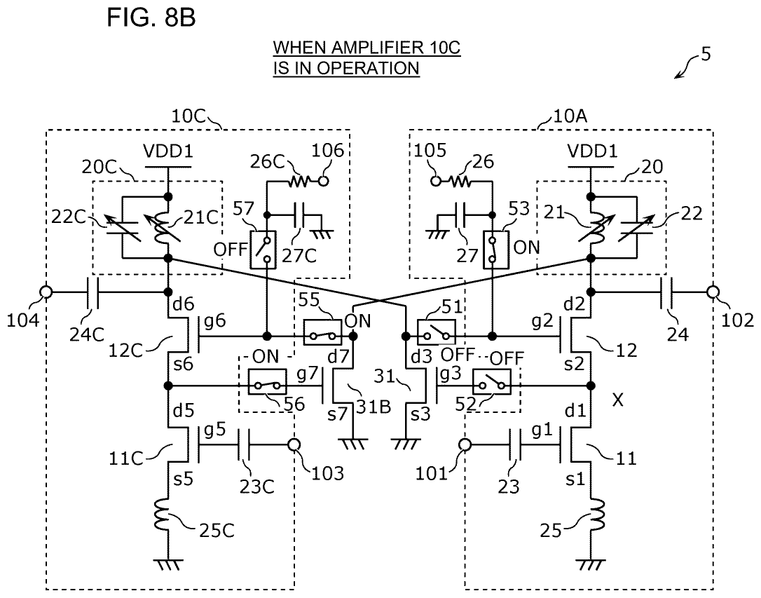

FIG. 8A is a circuit state diagram of the amplifier circuit 5 according to the fourth variation of the embodiment in which the amplifier 10A is in operation. When the amplifier 10A performs amplification with gain greater than a predetermined value, the switches 51 and 52 transition to a conductive state. On the other hand, the switch 53 transitions to a non-conductive state. Furthermore, the switches 55 and 56 transition to a non-conductive state. As a result, the FET 31 and the LC parallel resonant circuit 20C are connected to the amplifier 10A. That is, when the amplifier 10A performs amplification with high gain, the FET 31 and the LC parallel resonant circuit 20C function as an auxiliary amplifier for the amplifier 10A. In this state, the amplifier circuit 5 can amplify a radio frequency signal inputted to the input terminal 101 with high gain while maintaining low power consumption.

Also, although not illustrated, when the amplifier 10A performs amplification with gain less than or equal to the predetermined value, the switches 51 and 52 transition to a non-conductive state. On the other hand, the switch 53 transitions to a conductive state. In this case, no auxiliary amplifier is connected to the amplifier 10A, the gate terminal g2 is high-frequency grounded, a bias voltage is supplied to the gate terminal g2 from the bias terminal 105, and the amplifier circuit 5 is enabled to amplify a radio frequency signal inputted to the input terminal 101 with low gain.

FIG. 8B is a circuit state diagram of the amplifier circuit 5 according to the fourth variation of the embodiment in which the amplifier 10C is in operation. When the amplifier 10C performs amplification with gain greater than a predetermined value, the switches 55 and 56 transition to a conductive state. On the other hand, the switch 57 transitions to a non-conductive state. Furthermore, the switches 51 and 52 transition to a non-conductive state. As a result, the FET 31B and the LC parallel resonant circuit 20 are connected to the amplifier 10C. That is, when the amplifier 10C performs amplification with high gain, the FET 31B and the LC parallel resonant circuit 20 function as an auxiliary amplifier for the amplifier 10C. In this state, the amplifier circuit 5 can amplify a radio frequency signal inputted to the input terminal 103 with high gain while maintaining low power consumption.

Also, although not illustrated, when the amplifier 10C performs amplification with gain less than or equal to the predetermined value, the switches 55 and 56 transition to a non-conductive state. On the other hand, the switch 57 transitions to a conductive state. In this case, no auxiliary amplifier is connected to the amplifier 10C, the gate terminal g6 is high-frequency grounded, a bias voltage is supplied to the gate terminal g6 from the bias terminal 106, and the amplifier circuit 5 is enabled to amplify a radio frequency signal inputted to the input terminal 103 with low gain.

With this configuration, the amplifier circuit 5 can select either the low-gain mode or the high-gain mode with low power consumption as appropriate by controlling the switches 51, 52, 53, 55, 56, and 57. This configuration also makes it possible to use a part (an LC parallel resonant circuit) of an amplifier in the off state as an auxiliary amplifier. This in turn makes it possible to provide the amplifier circuit 5 with increased gain and less area while maintaining low power consumption.

### 6 Effects

As described above, the amplifier circuit 1 according to the present embodiment includes the input terminal 101; the output terminal 102; the FET 11 including the gate terminal g1, the drain terminal d1, and the source terminal s1; the FET 12 including the gate terminal g2, the drain terminal d2, and the source terminal s2; the FET 31 including the gate terminal g3, the drain terminal d3, and the source terminal s3; and the LC parallel resonant circuits 20 and 40. The gate terminal g1 is connected to the input terminal 101, the drain terminal d1 is connected to the source terminal s2, the source terminal s1 is connected to the ground, the gate terminal g2 is connected to the drain terminal d3 and the LC parallel resonant circuit 40, the drain terminal d2 is connected to the output terminal 102 and the LC parallel resonant circuit 20, the gate terminal g3 is connected to the source terminal s2, and the source terminal s3 is connected to the ground.

With this configuration, because the variation at the X point (the connection point between the drain terminal d1 and the source terminal s2) is small, the drain-source voltage Vds of the FET 12 does not vary, and the amplitude of the drain current Id varies depending on the gate-source voltage Vgs. In this case, because the drain current Id does not vary according to the variation in the drain-source voltage Vds, the drain-source resistance of the FET 12 becomes very high. That is, it is possible to greatly increase the output resistance Rout and increase the gain A by applying a small electric current to the auxiliary amplifier 30. This in turn makes it possible to provide the amplifier circuit 1 with increased gain while maintaining low power consumption.

Also, for example, in the amplifier circuit 1, each of the LC parallel resonant circuits 20 and 40 varies the resonant frequency according to the frequency of a radio frequency signal inputted to the input terminal 101.

This makes it possible to increase the gain in a desired frequency and also makes it possible to direct an unnecessary frequency component toward a power supply terminal.

Also, for example, the amplifier circuit 2 according to the first variation further includes the switch 52 that connects and disconnects the source terminal s2 and the gate terminal g3, and the switch 51 that connects and disconnects the gate terminal g2 and the drain terminal d3.

Also, for example, in the amplifier circuit 2, when the gain of the amplifier circuit 2 is greater than the predetermined value, the switches 51 and 52 transition to a conductive state; and when the gain of the amplifier circuit 2 is less than or equal to the predetermined value, the switches 51 and 52 transition to a non-conductive state.

With this configuration, the amplifier circuit 2 can select either the low-gain mode or the high-gain mode with low power consumption as necessary by changing the conductive and non-conductive states of the switches 51 and 52.

Also, for example, the amplifier circuit 2 further includes the resistor element 26 connected between the gate terminal g2 and the bias terminal 105, and the capacitor 27 connected between the gate terminal g2 and the ground.

This configuration makes it possible to select between a high-gain mode in which the gate terminal g2 is connected to the auxiliary amplifier 30 and a low-gain mode in which the gate terminal g2 is connected to the bias terminal 105.

Also, for example, in the amplifier circuits 1 and 2, the FETs 11 and 12 are cascoded.

This configuration makes it possible to provide the amplifier circuits 1 and 2 that are capable of performing high-gain amplification.

Also, for example, the amplifier circuit 3 according to the second variation further includes the FET 32 including the gate terminal g4, the drain terminal d4, and the source terminal s4. The FET 32 is connected between the drain terminal d3 and the LC parallel resonant circuit 40. The gate terminal g4 is connected to the bias terminal 105, the drain terminal d4 is connected to the LC parallel resonant circuit 40, the source terminal s4 is connected to the drain terminal d3, and the gate terminal g2 is connected to the drain terminal d3 via the drain terminal d4 and the source terminal s4.

This configuration makes it possible to suppress the miller effect and thereby makes it possible to improve reverse isolation and improve the K factor.

Also, for example, in the amplifier circuit 3, the FETs 31 and 32 are cascoded.

This makes it possible to provide the amplifier circuit 3 that achieves high gain with lower current consumption.

Also, for example, the amplifier circuit 4 according to the third variation further includes the input terminal 103; the output terminal 104; the FET 11B including the gate terminal g5, the drain terminal d5, and the source terminal s5; the FET 12B including the gate terminal g6, the drain terminal d6, and the source terminal s6; and the FET 31B including the gate terminal g7, the drain terminal d7, and the source terminal s7. The gate terminal g1 is connected to the input terminal 101, the gate terminal g5 is connected to the input terminal 103, the drain terminal d1 is connected to the source terminal s2, the drain terminal d5 is connected to the source terminal s6, the source terminals s1 and s5 are connected to the ground, the gate g2 is connected to the drain terminal d3 and the LC parallel resonant circuit 20B, the gate terminal g6 is connected to the drain terminal d7 and the LC parallel resonant circuit 20, the drain terminal d2 is connected to the output terminal 102 and the LC parallel resonant circuit 20, the drain terminal d6 is connected to the output terminal 104 and the LC parallel resonant circuit 20B, the gate terminal g3 is connected to the source terminal s2, the gate terminal g7 is connected to the source terminal s6, and the source terminals s3 and s7 are connected to the ground.

This configuration makes it possible to use a part (an LC parallel resonant circuit) of an amplifier in the off state as an auxiliary amplifier. This in turn makes it possible to provide the amplifier circuit 4 with increased gain and less area while maintaining low power consumption.

Also, for example, the amplifier circuit 5 according to the fourth variation further includes the switch 52 that connects and disconnects the source terminal s2 and the gate terminal g3, the switch 51 that connects and disconnects the gate terminal g2 and the drain terminal d3, the switch 56 that connects and disconnects the source terminal s6 and the gate terminal g7, and the switch 55 that connects and disconnects the gate terminal g6 and the drain terminal d7.

Also, for example, in the amplifier circuit 5, when the FETs 11 and 12 are caused to perform amplification with gain greater than the predetermined value, the switches 51 and 52 transition to a conductive state, and the switches 55 and 56 transition to a non-conductive state. On the other hand, when the FETs 11C and 12C are caused to perform amplification with gain greater than the predetermined value, the switches 51 and 52 transition to a non-conductive state, and the switches 55 and 56 transition to a conductive state.

With this configuration, the amplifier circuit 5 can select either the low-gain mode or the high-gain mode with low power consumption as appropriate by controlling the switches 51, 52, 55, and 56. This configuration also makes it possible to use a part (an LC parallel resonant circuit) of an amplifier in the off state as an auxiliary amplifier. This in turn makes it possible to provide the amplifier circuit 5 with increased gain and less area while maintaining low power consumption.

Also, for example, in the amplifier circuit 4, the FETs 11B and 12B are cascoded. Furthermore, for example, in the amplifier circuit 5, the FETs 11C and 12C are cascoded.

This configuration makes it possible to provide the amplifier circuits 4 and 5 that are capable of performing high-gain amplification.

### Other Embodiments

Amplifier circuits according to the embodiment of the present disclosure and the variations of the embodiment are described above. However, the present disclosure is not limited to the amplifier circuits of the embodiment and the variations described above. The present disclosure may also include other embodiments implemented by combining components in the above embodiment and variations, other variations obtained by making various modifications conceivable by a person skilled in the art to the embodiment and variations without departing from the spirit of the present disclosure, and various devices including the amplifier circuits described above.

For example, in the circuit configurations of the amplifier circuits according to the embodiment and variations described above, another circuit element and/or a wire may be inserted between paths connecting circuit elements and signal paths illustrated in the drawings.

Features of the amplifier circuits described in the above embodiment and variations are described below.
<1> An amplifier circuit includes a first input terminal; a first output terminal; a first amplifying element including a first control terminal, a first terminal, and a second terminal; a second amplifying element including a second control terminal, a third terminal, and a fourth terminal; a third amplifying element including a third control terminal, a fifth terminal, and a sixth terminal; a first LC parallel resonant circuit; and a second LC parallel resonant circuit. The first control terminal is connected to the first input terminal, the first terminal is connected to the fourth terminal, the second terminal is connected to a ground, the second control terminal is connected to the fifth terminal and the second LC parallel resonant circuit, the third terminal is connected to the first output terminal and the first LC parallel resonant circuit, the third control terminal is connected to the fourth terminal, and the sixth terminal is connected to the ground.
<2> In the amplifier circuit described in <1>, the first LC parallel resonant circuit and the second LC parallel resonant circuit vary resonant frequencies according to the frequency of a radio frequency signal inputted to the first input terminal.
<3> The amplifier circuit described in <1> or <2> further includes a first switch that connects and disconnects the fourth terminal and the third control terminal; and a second switch that connects and disconnects the second control terminal and the fifth terminal.
<4> In the amplifier circuit described in <3>, when the gain of the amplifier circuit is greater than a predetermined value, the first switch and the second switch transition to a conductive state; and when the gain of the amplifier circuit is less than or equal to the predetermined value, the first switch and the second switch transition to a non-conductive state.
<5> The amplifier circuit described in any one of <1> to <4> further includes a resistor element connected between the second control terminal and a bias terminal; and a capacitor connected between the second control terminal and the ground.
<6> In the amplifier circuit described in any one of <1> to <4>, the first amplifying element and the second amplifying element are cascoded.
<7> The amplifier circuit described in any one of <1> to <6> further includes a fourth amplifying element including a fourth control terminal, a seventh terminal, and an eighth terminal. The fourth amplifying element is connected between the fifth terminal and the second LC parallel resonant circuit, the fourth control terminal is connected to the bias terminal, the seventh terminal is connected to the second LC parallel resonant circuit, the eighth terminal is connected to the fifth terminal, and the second control terminal is connected to the fifth terminal via the seventh terminal and the eighth terminal.
<8> In the amplifier circuit described in <7>, the third amplifying element and the fourth amplifying element are cascoded.
<9> The amplifier circuit described in <1> or <2> further includes a second input terminal; a second output terminal; a fifth amplifying element including a fifth control terminal, a ninth terminal, and a tenth terminal; a sixth amplifying element including a sixth control terminal, an eleventh terminal, and a twelfth terminal; and a seventh amplifying element including a seventh control terminal, a thirteenth terminal, and a fourteenth terminal. The first control terminal is connected to the first input terminal, the fifth control terminal is connected to the second input terminal, the first terminal is connected to the fourth terminal, the ninth terminal is connected to the twelfth terminal, the second terminal is connected to the ground, the tenth terminal is connected to the ground, the second control terminal is connected to the fifth terminal and the second LC parallel resonant circuit, the sixth control terminal is connected to the thirteenth terminal and the first LC parallel resonant circuit, the third terminal is connected to the first output terminal and the first LC parallel resonant circuit, the eleventh terminal is connected to the second output terminal and the second LC parallel resonant circuit, the third control terminal is connected to the fourth terminal, the seventh control terminal is connected to the twelfth terminal, the sixth terminal is connected to the ground, and the fourteenth terminal is connected to the ground.
<10> The amplifier circuit described in <9> further includes a third switch that connects and disconnects the fourth terminal and the third control terminal; a fourth switch that connects and disconnects the second control terminal and the fifth terminal; a fifth switch that connects and disconnects the twelfth terminal and the seventh control terminal; and a sixth switch that connects and disconnects the sixth control terminal and the thirteenth terminal.
<11> In the amplifier circuit described in <10>, when the first amplifying element and the second amplifying element are caused to perform amplification with gain greater than a predetermined value, the third switch and the fourth switch transition to a conductive state, and the fifth switch and the sixth switch transition to a non-conductive state; and when the fifth amplifying element and the sixth amplifying element are caused to perform amplification with gain greater than the predetermined value, the third switch and the fourth switch transition to the non-conductive state, and the fifth switch and the sixth switch transition to the conductive state.
<12> In the amplifier circuit described in any one of <9> to <11>, the fifth amplifying element and the sixth amplifying element are cascoded.

The present disclosure can be widely used for communication devices, such as mobile phones, as a power amplifier circuit disposed in a multiband front-end unit.

What is claimed is:

1. An amplifier circuit comprising:
a first input terminal;
a first output terminal;
a first amplifying circuit element having a first control terminal, a first terminal, and a second terminal;
a second amplifying circuit element having a second control terminal, a third terminal, and a fourth terminal;
a third amplifying circuit element having a third control terminal, a fifth terminal, and a sixth terminal;
a first LC parallel resonant circuit; and
a second LC parallel resonant circuit,
wherein the first control terminal is connected to the first input terminal,
wherein the first terminal is connected to the fourth terminal,
wherein the second terminal is connected to ground,
wherein the second control terminal is connected to the fifth terminal and to the second LC parallel resonant circuit,
wherein the third terminal is connected to the first output terminal and to the first LC parallel resonant circuit,
wherein the third control terminal is connected to the fourth terminal, and
wherein the sixth terminal is connected to ground.

2. The amplifier circuit according to claim 1, wherein the first LC parallel resonant circuit and the second LC parallel resonant circuit are configured to vary resonant frequencies according to a frequency of a radio frequency signal input to the first input terminal.

3. The amplifier circuit according to claim 1, further comprising:
a first switch that selectively connects the fourth terminal to the third control terminal; and
a second switch that selectively connects the second control terminal to the fifth terminal.

4. The amplifier circuit according to claim 3,
wherein when a gain of the amplifier circuit is greater than a predetermined value, the first switch and the second switch are configured to transition to a conductive state; and
wherein when the gain of the amplifier circuit is less than or equal to the predetermined value, the first switch and the second switch are configured to transition to a non-conductive state.

5. The amplifier circuit according to claim 3, further comprising:
a resistor circuit element connected between the second control terminal and a bias terminal; and
a capacitor connected between the second control terminal and ground.

6. The amplifier circuit according to claim 1, wherein the first amplifying circuit element and the second amplifying circuit element are cascode connected.

7. The amplifier circuit according to claim 1, further comprising:
a fourth amplifying circuit element having a fourth control terminal, a seventh terminal, and an eighth terminal,
wherein the fourth amplifying circuit element is connected between the fifth terminal and the second LC parallel resonant circuit,
wherein the fourth control terminal is connected to the bias terminal,
wherein the seventh terminal is connected to the second LC parallel resonant circuit,
wherein the eighth terminal is connected to the fifth terminal, and
wherein the second control terminal is connected to the fifth terminal via the seventh terminal and the eighth terminal.

8. The amplifier circuit according to claim 7, wherein the third amplifying circuit element and the fourth amplifying circuit element are cascode connected.

9. The amplifier circuit according to claim 1, further comprising:
a second input terminal;
a second output terminal;
a fifth amplifying circuit element having a fifth control terminal, a ninth terminal, and a tenth terminal;
a sixth amplifying circuit element having a sixth control terminal, an eleventh terminal, and a twelfth terminal; and
a seventh amplifying circuit element having a seventh control terminal, a thirteenth terminal, and a fourteenth terminal,
wherein the first control terminal is connected to the first input terminal,
wherein the fifth control terminal is connected to the second input terminal,
wherein the first terminal is connected to the fourth terminal,
wherein the ninth terminal is connected to the twelfth terminal,
wherein the second terminal is connected to ground,
wherein the tenth terminal is connected to ground,
wherein the second control terminal is connected to the fifth terminal and to the second LC parallel resonant circuit,
wherein the sixth control terminal is connected to the thirteenth terminal and to the first LC parallel resonant circuit,
wherein the third terminal is connected to the first output terminal and to the first LC parallel resonant circuit,
wherein the eleventh terminal is connected to the second output terminal and to the second LC parallel resonant circuit,
wherein the third control terminal is connected to the fourth terminal,
wherein the seventh control terminal is connected to the twelfth terminal,
wherein the sixth terminal is connected to ground, and
wherein the fourteenth terminal is connected to ground.

10. The amplifier circuit according to claim 9, further comprising:
a third switch that connects and disconnects the fourth terminal and the third control terminal;
a fourth switch that connects and disconnects the second control terminal and the fifth terminal;
a fifth switch that connects and disconnects the twelfth terminal and the seventh control terminal; and
a sixth switch that connects and disconnects the sixth control terminal and the thirteenth terminal.

11. The amplifier circuit according to claim 10,
wherein when the first amplifying circuit element and the second amplifying circuit element perform amplification with a gain greater than a predetermined value, the third switch and the fourth switch are configured to transition to a conductive state, and the fifth switch and the sixth switch are configured to transition to a non-conductive state; and
wherein when the fifth amplifying circuit element and the sixth amplifying circuit element perform amplification with a gain greater than the predetermined value, the third switch and the fourth switch are configured to transition to the non-conductive state, and the fifth switch and the sixth switch are configured to transition to the conductive state.

12. The amplifier circuit according to claim 9, wherein the fifth amplifying circuit element and the sixth amplifying circuit element are cascode connected.
